(19) United States
(12) Patent Application Publication
(10) Pub. No.: US 2004/0049722 A1
(43) Pub. Date: Mar. 11, 2004

(54) Failure analysis system, failure analysis method, a computer program product and a manufacturing method for a semiconductor device

(75) Inventor: Hiroshi Matsushita, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/608,155

(22) Filed: Jun. 30, 2003

(30) Foreign Application Priority Data
Sep. 9, 2002 (JP) 2002-263277

(51) Int. Cl. G01R 31/28

(52) U.S. Cl. 714/724

(57) ABSTRACT

A failure analysis system, includes a chip position calculation module configured to calculate fault chip positions of a plurality of circuit blocks in a chip region based on layout information on the circuit blocks positioned in the chip region and fault information on the circuit blocks; a wafer position calculation module configured to calculate fault wafer positions in a wafer based on the fault chip positions and position information showing a chip region layout in a wafer plane; and a mapping module configured to perform a mapping display of the fault wafer positions in accordance with physical coordinates on the wafer plane.

### CROSS REFERENCE TO RELATED APPLICATIONS

This application is based upon and claims the benefit of priority from prior Japanese Patent Application P2002-263277 filed on Sep. 9, 2002; the entire contents of which are incorporated by reference herein.

### BACKGROUND OF THE INVENTION

1. Field of the Invention

The present invention relates to a failure analysis system for analyzing a cause of a decreased yield in a manufacturing process of a semiconductor device, a failure analysis method, a computer program product and a manufacturing method for a semiconductor device using the same.

2. Description of the Related Art

In order to improve the manufacturing yield of a LSI, it is important to analyze a yield loss and to promptly ascertain and improve a manufacturing process, a manufacturing apparatus or a design condition, which causes the yield loss. Along with advances in miniaturization of semiconductor devices in recent years, various failures attributable to manufacturing processes have become apparent. In order to provide measures to prevent or decrease the failures, it is important to analyze a fail bit map (FBM) and an in-line defect map. Specifically, in the fail bit map, test information obtained in memory products immediately after completion of a wafer process is displayed by mapping. Failure distributions within a wafer plane are classified into a random failure distribution and a cluster failure distribution. The cluster failure distribution is considered to be triggered by a systematic factor attributable to a manufacturing process, a manufacturing apparatus and the like and is a significant cause of decreasing the manufacturing yield. Therefore, extraction of the cluster faults from the failure distribution is the first step of clarifying the cause of the failure and a technique for the extraction has been proposed (refer to K. Mitsutake, Y. Ushiku, Y. Arakawa, T. Ishibumi, and O. Ito, “New method of extraction of systematic failure component”, Proc. 10th Int. Symp. Semiconductor Manufacturing, 2001, pp247-250). The failure attributable to the manufacturing process, the manufacturing apparatus and the like generates fault patterns on the wafer plane, which are inherent in the process and the manufacturing apparatus. Therefore, pattern analysis of the cluster faults can be regarded as a clue for clarifying the cause of generation of the failure. Accordingly, as the second step of clarifying the cause of the failure, analysis of such fault patterns on the wafer plane has been performed. Based on a micro classification of the fail bit maps of the memory products (a bit fault, a row fault, a column fault and the like), the physical cause can be estimated (open fault or short fault of wiring, a layer in which the open or short faults of wiring occurs and the like). Moreover, identification of the cause of the failure is attempted by a macro classification of the fail bit maps on the wafer plane. Moreover, it has been reported that a classification of seven kinds of fault modes can be performed by use of a probability distribution function waveform of a distance between the fail bits on the fail bit map (refer to M. Sugimoto, M. Tanaka, “Characterization algorithm of failure distribution for LSI yield improvement,” Proc. 8th Int. Symp. Semiconductor Manufacturing, 2001, pp. 275-278). Moreover, it has been reported that a classification of fifty-five kinds of fault modes is performed by combining the macro classification of the fail bit maps (a distribution of positions in a wafer plane) and the micro classification. Furthermore, a pattern classification by a neural network has also been attempted by analyzing fail bit maps in a computer as an image (refer to K. Nakamae, A. Itoh, and H. Fujioka, “Fail pattern classification and analysis system of memory fail bit maps,” Proc. 4th Int. Conf. Modeling and Simulation of Microsystems, 2001, pp. 598-601). Still furthermore, a fail bit count (FBC) data method has been proposed, in which fail bits are counted by a minute division unit in memory products. Thus, the fail bit maps and the fail bit count, which are obtained in the memory products, provide extremely useful information in the classification of fail patterns.

Recently, in semiconductor integrated circuits, the production scale of a system LSI merging a microprocessing unit, a logic circuit, an analog circuit, a memory block and the like in a single semiconductor chip has been expanded. As to the memory block merged in such a system LSI, in many cases, memory blocks are smaller in size than general-purpose memory products and exist as separated in a plurality of chip regions. In that case, recognition of fail patterns by confirming fail bit maps divided into multiple parts is extremely difficult. Moreover, obtaining fail bit maps requires longer time by a tester and thus it is difficult to obtain the fail bit maps in all produced wafers. There has been a problem that an increase in the number of wafers to obtain fail bit maps decreases productivity of a manufacturing facility. Moreover, there has also been a problem that a conventional automatic failure classification system cannot classify fault modes unknown to the system.

### SUMMARY OF THE INVENTION

A first aspect of the present invention inheres in a failure analysis system, and includes: a chip position calculation module configured to calculate fault chip positions of a plurality of circuit blocks in a chip region based on layout information on the plurality of circuit blocks positioned in the chip region and fault information on the plurality of circuit blocks; a wafer position calculation module configured to calculate fault wafer positions in a wafer based on the fault chip positions and position information showing a chip region layout in a wafer plane; and a mapping module configured to perform a mapping display of the fault wafer positions in accordance with physical coordinates on the wafer plane.

A second aspect of the present invention inheres in a failure analysis method, and includes: reading out layout information on a plurality of circuit blocks disposed in a chip region, position information showing a chip region layout in a wafer plane and fault information on the circuit blocks; calculating fault chip positions in the chip region of the circuit blocks based on the layout information and the fault information; calculating fault wafer positions in a wafer based on the position information and the fault chip positions; and subjecting the fault wafer positions to a mapping display in accordance with physical coordinates on the wafer plane.

A third aspect of the present invention inheres in a computer program product configured to be executed by a computer, and includes: an instruction of reading out layout information on a plurality of circuit blocks disposed in a chip region, position information showing a chip region layout in a wafer plane and fault information on the circuit blocks; an instruction of calculating fault chip positions in a chip region of the circuit blocks based on the layout information and the fault information; an instruction of calculating fault wafer positions in a wafer based on the position information and the fault chip positions; and an instruction of subjecting the fault wafer positions to a mapping display in accordance with physical coordinates on the wafer plane.

A fourth aspect of the present invention inheres in a manufacturing method for a semiconductor device, and includes: fabricating a plurality of integrated circuits on a wafer, by assigning a plurality of chip regions for each of the integrated circuits such that each of the chip regions has a plurality of circuit blocks disposed therein, by sequentially executing a plurality of manufacturing processes; obtaining fault information by measuring characteristics of the circuit blocks, respectively; detecting a fault based on a result of a mapping display performed for the fault information in accordance with physical coordinates on a wafer plane by use of layout information on the circuit blocks disposed in the chip region; and performing at least one of a repair of a manufacturing apparatus used for the manufacturing, a remodeling of the manufacturing apparatus, and a modification of a recipe of a specific manufacturing process in the plurality of manufacturing processes causing the fault to occur.

### BRIEF DESCRIPTION OF DRAWINGS

FIG. 1 is a chip layout view of a system LSI including a plurality of circuit blocks.

FIG. 2 is a schematic view of fail bit maps of the respective circuit blocks.

FIG. 3 is a block diagram of a failure analysis system according to a first embodiment of the present invention.

FIG. 4 is a flowchart showing a failure analysis method according to the first embodiment of the present invention.

FIG. 5 is a mapping display result of the fail bit map of each circuit block on a wafer plane.

FIG. 6 is a schematic view of pass/fail maps of the respective circuit blocks.

FIG. 7 is a mapping display result of the pass/fail map of each circuit block on the wafer plane.

FIG. 8 is a schematic view of pass/fail maps of respective circuit blocks on a wafer having more faults in a wafer periphery.

FIG. 9 is a schematic view of a pass/fail map by a chip of the wafer having more faults in the wafer periphery.

FIG. 10 is a mapping display result, on the wafer plane, of the pass/fail maps of the respective circuit blocks of the wafer having more faults in the wafer periphery.

FIG. 11 is a block diagram of a failure analysis system according to a second embodiment of the present invention.

FIG. 12 is a flowchart showing a failure analysis method according to the second embodiment of the present invention.

FIG. 13 is a graph showing a definition of fault-extracting index representing the geometrical characteristics of an arc periphery fault.

FIG. 14 is a block diagram of a failure analysis system according to a third embodiment of the present invention.

FIG. 15 is a flowchart showing a failure analysis method according to the third embodiment of the present invention.

FIG. 16 is a mapping display result, on a wafer plane, of pass/fail maps of respective circuit blocks of a wafer having more faults in a wafer periphery.

FIG. 17 is a view showing a regional definition of second fault-extracting index for extracting all periphery faults.

FIG. 18 is a distribution map of parameter values for extracting all the periphery faults.

FIG. 19 is a graph showing a definition of the second fault-extracting index for extracting all the periphery faults.

FIG. 20 is a view showing a hierarchical structure of characteristics for automatically classifying unknown fault patterns.

FIG. 21 is a flowchart for explaining a manufacturing method for semiconductor device according to an embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

First Embodiment

A failure analysis system according to a first embodiment of the present invention enables fault modes on a wafer plane to be easily recognized in a mixed system LSI having a plurality of circuit blocks such as memory blocks.

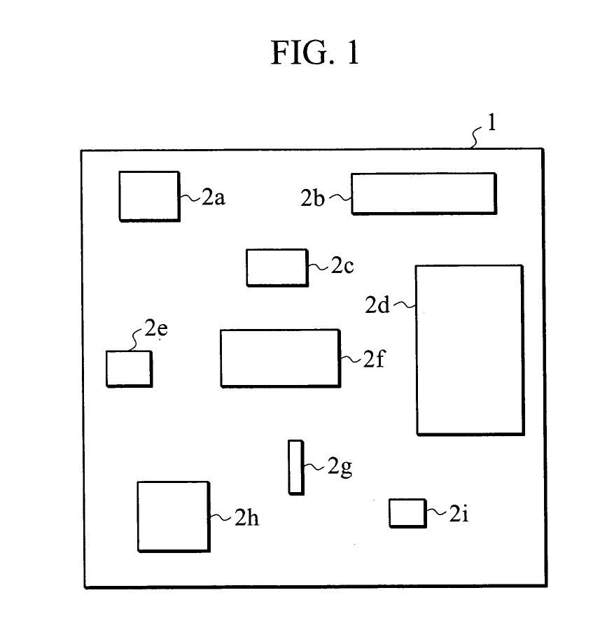

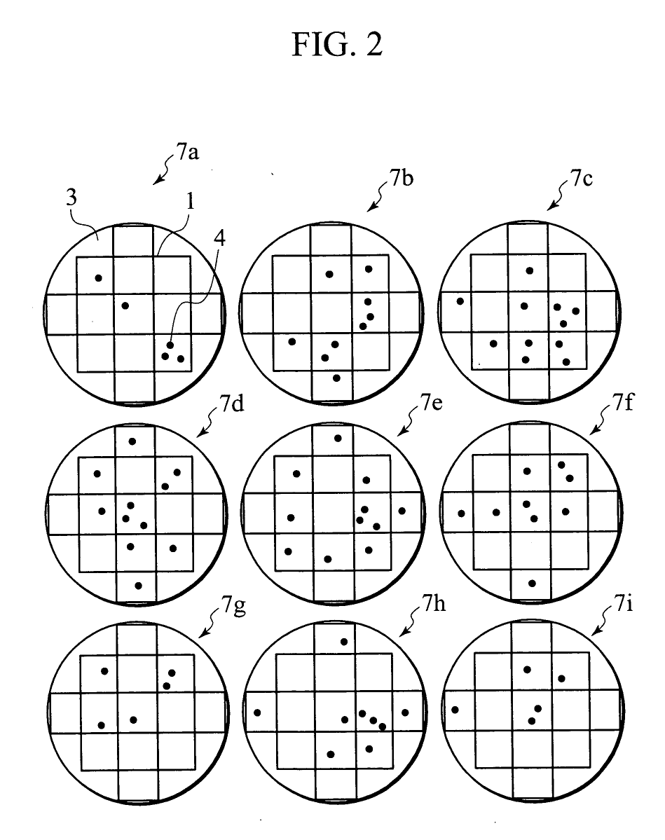

FIG. 1 is one example of a layout structure of the plurality of circuit blocks disposed in a chip region 1 of the system LSI to be a target in the embodiment of the present invention. In the system LSI, a microprocessing unit, a logic circuit and the like usually occupy a large part of the chip estate. However, in the embodiment of the present invention, as shown in FIG. 1, shown is a case where small capacity (several kilobytes) SRAM blocks (hereinafter referred to as circuit blocks) 2a to 2i are provided in nine scattered locations. FIG. 2 is a view schematically showing fail bit maps 7a to 7i obtained as a result of testing electrical characteristics of the respective circuit blocks 2a to 2i on a wafer 3 after completion of a wafer process of the SRAM. FIG. 2 schematically shows a case where thirteen chip regions 1 are disposed on the wafer 3. However, the number of the chip regions 1 disposed on the wafer 3 is determined by a relationship between an area of the chip region 1 and an area of the wafer 3. In general, as for the chip region 1, a size of 10 mm to 20 mm is used, and as for the wafer 3, a diameter of 200 mm to 300 mm or the like is used. Corresponding to the respective circuit blocks 2a to 2i shown in FIG. 1, the nine fail bit maps 7a to 7i are obtained. In FIG. 2, spots shown by dots represent fail bits 4. As shown in FIG. 2, from these schematically shown fail bit maps 7a to 7i, only a state where the fail bits 4 are randomly distributed can be seen. Consequently, in the first embodiment of the present invention, by use of layout information on the plurality of circuit blocks disposed in the chip region, the fail bit maps of the respective circuit blocks are displayed by mapping in accordance with physical coordinates on the wafer plane.

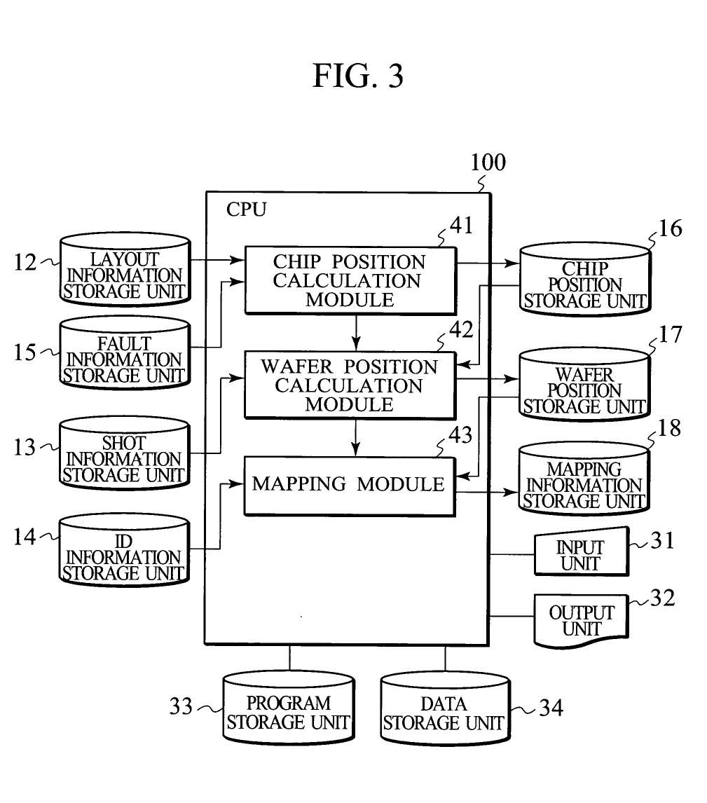

As shown in FIG. 3, the failure analysis system according to the first embodiment includes: a layout information storage unit 12; a shot information storage unit 13; an ID information storage unit 14; a fault information storage unit 15; a chip position storage unit 16; a wafer position storage unit 17; a mapping information storage unit 18; and a central processing unit (CPU) 100. Furthermore, an input unit 31, an output unit 32, a program storage unit 33 and a data storage unit 34 are connected to the CPU 100. Still further, the CPU 100 includes a chip position calculation module 41, a wafer position calculation module 42 and a mapping module 43.

The input unit 31 refers to instruments such as a keyboard, a mouse and the like. When an input operation is performed by the input unit 31, corresponding key information is transmitted to the CPU 100. The output unit 32 refers to a screen such as a monitor or the like and a liquid crystal display (LCD), a light-emitting diode (LED) panel, an electroluminescence (EL) panel and the like. This output unit 32 is controlled by the mapping module 43 of the CPU 100 and displays a mapping display result and the like. The program storage unit 33 stores programs for allowing the CPU 100 to execute a calculation of positions of the faults in a chip region, a calculation of positions of the faults in a wafer, a display of mapping information and the like. The data storage unit 34 temporarily stores data in the middle of a calculation or an analysis in operations by the CPU 100.

The layout information storage unit 12 stores layout information on a plurality of circuit blocks disposed in the chip region. The shot information storage unit 13 stores shot information indicating layout positions of chip regions in a wafer plane. The ID information storage unit 14 stores wafer ID information, such as an ID number, for identifying a wafer. The fault information storage unit 15 stores fault information such as fail bit maps or pass/fail maps. Specifically, the fault information storage unit 15 stores, as the fault information, fail bit maps obtained as a result of testing electrical characteristics of the respective circuit blocks on the wafer after completion of a wafer process, pass/fail maps obtained as a result of testing the electrical characteristics thereof while the circuit blocks are still in a wafer form before an assembly process and the like.

The chip position calculation module 41 calculates positions of respective fail bits or failure circuit blocks in the chip region (hereinafter, referred to as “fault chip positions”) based on data in the fault information storage unit 15 and the layout information storage unit 12. This calculation procedure is carried out in accordance with a program read out from the program storage unit 33. Calculation results and the like, which are used in the middle of the calculation, are temporarily stored in the data storage unit 34. The calculated fault chip positions in the chip region are stored in the chip position storage unit 16.

The wafer position calculation module 42 calculates positions of respective fail bits or failure circuit blocks in the wafer (hereinafter, referred to as “fault wafer positions”) based on data in the chip position storage unit 16 and the shot information storage unit 13. This calculation procedure is carried out in accordance with a program read out from the program storage unit 33. Calculation results and the like, which are used in the middle of the calculation, are temporarily stored in the data storage unit 34. The calculated fault wafer positions in the wafer are stored in the wafer position storage unit 17. Moreover, the wafer position calculation module 42 determines whether the fault wafer positions of all the circuit blocks in the chip region are calculated. When there is a circuit block in the chip region, of which a fault chip position is not calculated, information to that effect is transmitted to the chip position calculation module 41.

Based on the data in the wafer position storage unit 17, the mapping module 43 performs a mapping display of the fault wafer positions in the wafer in accordance with physical coordinates on the wafer plane. This mapping procedure is carried out in accordance with a program read out from the program storage unit 33. A result of the mapping display is stored in the mapping information storage unit 18. The mapping module 43 determines whether mapping displays are performed for all target wafers. When there is a wafer for which no mapping display is performed, information to that effect is transmitted to the chip position calculation module 41. Moreover, a result of the mapping display can be also confirmed on a screen of the output unit 32 by the mapping module 43.

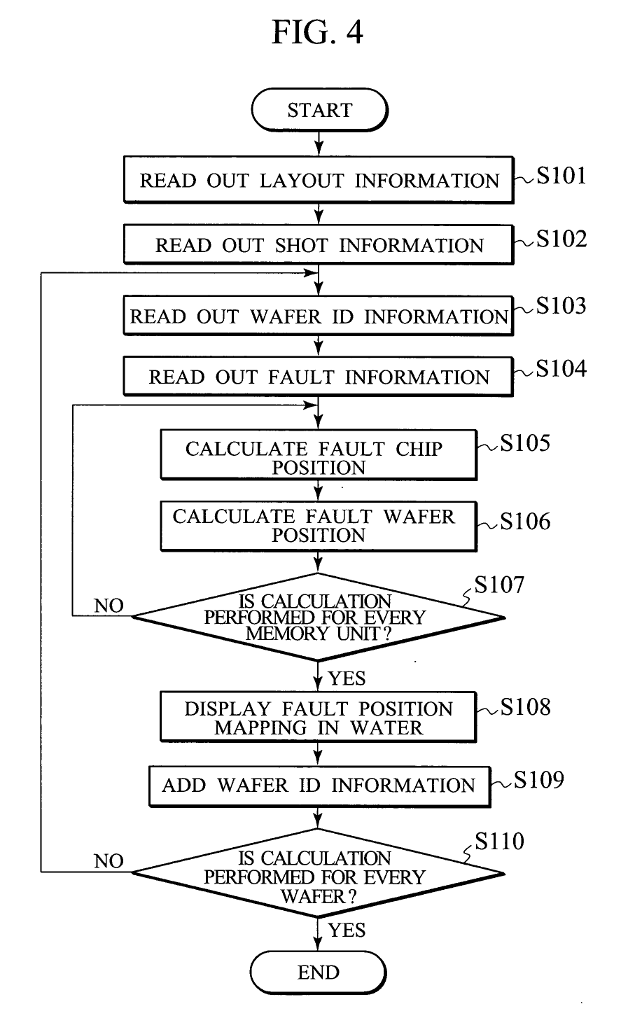

Next, with reference to FIG. 4, a description will be given of a failure analysis method according to the first embodiment of the present invention. Herein, a description is given of a case where fail bit maps are used as fault information.

(a) First, in Step S101, layout information on a plurality of circuit blocks in a chip region is read out from the layout information storage unit 12. Subsequently, in Step S102, shot position information indicating a layout of a plurality of chip regions located in a wafer plane is read out from the shot information storage unit 13. Then, in Step S103, wafer ID information such as ID numbers for identifying a plurality of wafers, respectively, is read out from the ID information storage unit 14. Next, in Step S104, fault information on fail bit maps is read out from the fault information storage unit 15. Specifically, the fail bit maps 7a to 7i, with respect to the plurality of wafers shown in FIG. 2, are inputted.

(b) In Step S105, based on the layout information read out in Step S101 and the fault information read out in Step S104, the chip position calculation module 41 calculates fault chip positions in the chip region. This calculation result is stored in the chip position storage unit 16.

(c) In Step S106, based on the shot position information read out in Step S102 and the fault chip positions in the chip region, which are calculated in Step S105, the wafer position calculation module 42 calculates fault wafer positions in the wafer. This calculation result is stored in the wafer position storage unit 17.

(d) Next, in Step S107, the wafer position calculation module 42 determines whether the fault wafer positions of all the circuit blocks in the chip region are calculated. When the fault wafer positions of all the circuit blocks in the chip region are not calculated, the processing returns to Step S105. When the fault wafer positions of all the circuit blocks in the chip region are calculated, the processing advances to Step S108.

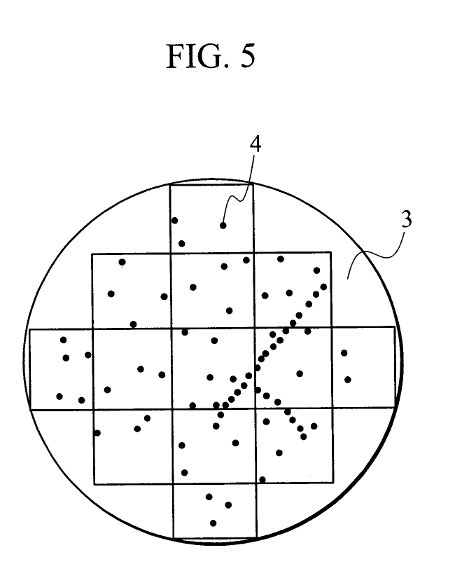

(e) In Step S108, the mapping module 43 performs a mapping display of the fault wafer positions in the wafer, which are calculated in Step S106, as shown in FIG. 5, in accordance with physical coordinates on the wafer plane. In FIG. 5, it is estimated that the fail bits 4 are lined up linearly and thus a scratch is present on the wafer plane.

(f) In Step S109, the mapping module 43 adds the wafer ID information read out in Step S103 to the mapping display result obtained in S108. This mapping display result added with the wafer ID information is stored in the mapping information storage unit 18.

(g) In Step S110, the mapping module 43 determines whether the processing from S105 to S108 is performed for all the target wafers. When the processing is not performed for all the target wafers, unprocessed wafers remain among the wafers in the wafer ID information read out in Step S103, thus returning to Step S103. When the processing is performed for all the target wafers, the processing is finished.

As described above, by use of the layout information on the plurality of circuit blocks disposed in the chip region, the fail bit maps are subjected to the mapping display in accordance with the physical coordinates on the wafer plane. Thus, more detailed position information on the fail bits and fault patterns can be recognized.

Next, in the failure analysis method according to the first embodiment of the present invention, a description will be given of a case of using pass/fail maps as fault information.

Normally, because a tester is occupied for a long time in order to obtain the fail bit maps, in many cases, the fail bit maps are only obtained for a part of a produced wafer. However, in a fault distribution in the wafer plane, problematic patterns inherent in a manufacturing process and a manufacturing apparatus are considered to appear. Thus, those patterns give an important clue for specifying a cause of the fault. In terms of a fault analysis, it is desirable to obtain as many fail bit maps as possible. However, decreased productivity of a factory attributable to an increase in fault test time must be avoided. Even if the fail bit maps are not obtained, there are cases where a test is performed on patterns which are in the form of a wafer before an assembly process and the pass/fail determination result, in other words, information on the pass/fail maps is provided. This test is performed for all the wafers and thus the information on the pass/fail maps becomes fault information, which is more abundant than the fail bit maps.

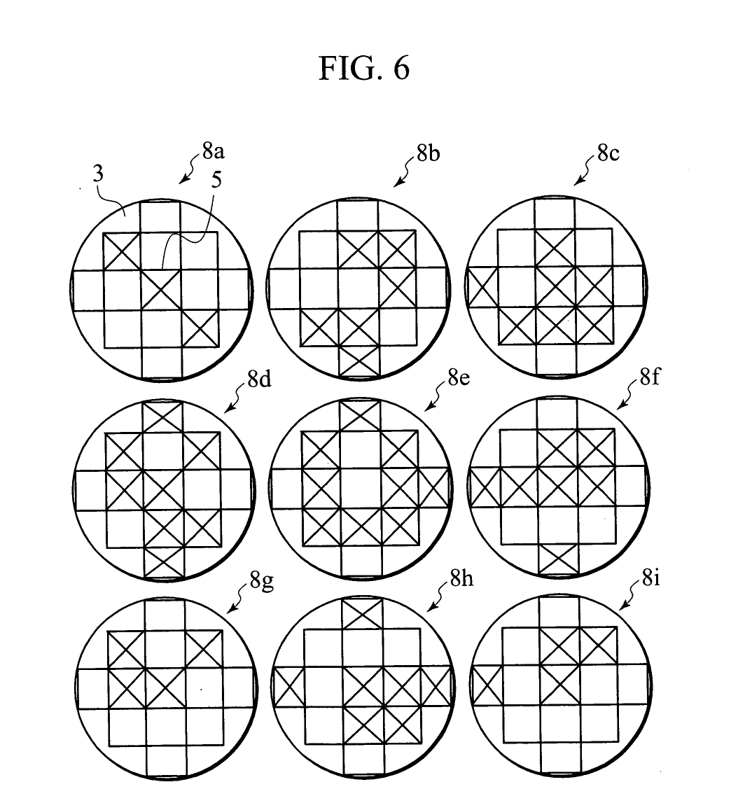

FIG. 6 is a view schematically showing pass/fail maps 8a to 8i obtained as a result of testing electrical characteristics in the state of the wafer form before the assembly process. Herein, it is based on the premise that pass/fail maps of the nine circuit blocks 2a to 2i in the chip region 1 shown in FIG. 1 are obtained for all the wafers. Corresponding to the nine circuit blocks 2a to 2i shown in FIG. 1, nine pass/fail maps 8a, 8b, . . . and 8i are obtained for the respective circuit blocks. In FIG. 6, spots indicated by christcross marks represent fault circuit blocks 5. As shown in FIG. 6, from these nine pass/fail maps 8a to 8i, it is difficult to recognize characteristic fault patterns on the wafer 3. Consequently, similar to the application of the above-described failure analysis method according to the first embodiment of the fail bit maps, by use of the layout information on the plurality of circuit blocks disposed in the chip region, the pass/fail maps of the respective circuit blocks are subjected to the mapping display in accordance with the physical coordinates on the wafer plane.

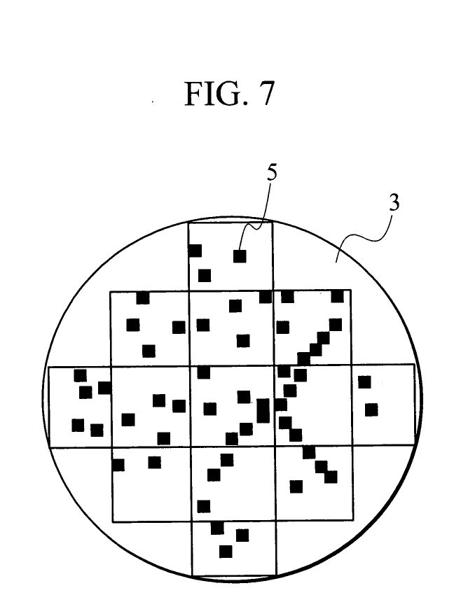

FIG. 7 shows a result of a mapping display performed for the pass/fail maps 8a to 8i in accordance with physical coordinates of the circuit blocks 2a to 2i. Specifically, the physical coordinates of the circuit blocks on the plane of the wafer 3 are obtained by use of the layout information on the respective circuit blocks in the chip region. As shown in FIG. 7, the mapping display performed by the fault circuit block 5 enables a scratch on the plane of the wafer 3 to be clearly recognized, with the similar spatial resolution for the result of the mapping display shown in FIG. 5, which is performed by the fail bit 4.

In the system LSI, a plurality of small capacitance circuit blocks exist as scattered in a chip region, in many cases. In such a case, the pass/fail maps of the respective memories are subjected to a mapping display in accordance with physical coordinates thereof on a wafer plane and thus fault pattern information having spatial resolution with a size of the chip region or less can be obtained.

As described above, according to the first embodiment of the present invention, the fault pattern information in the system LSI can be obtained with high spatial resolution and without decreasing productivity of a factory.

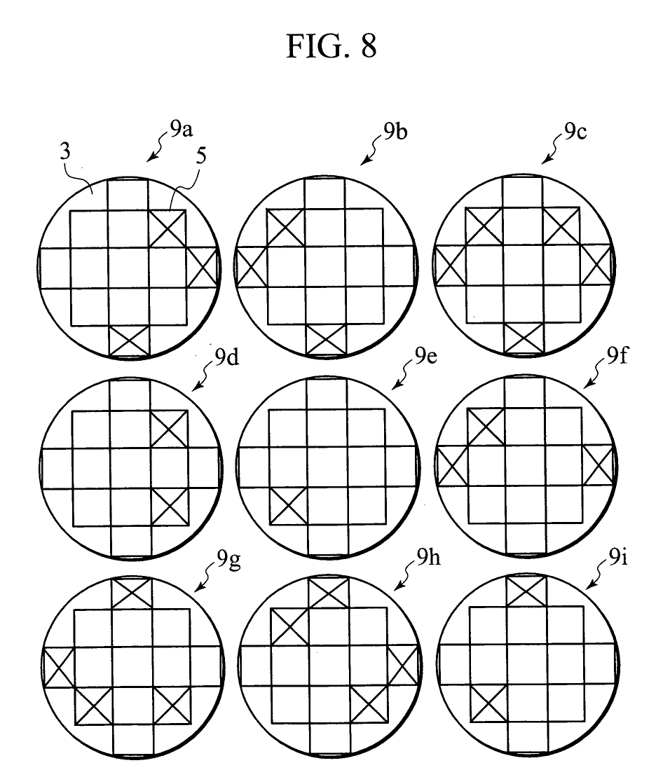

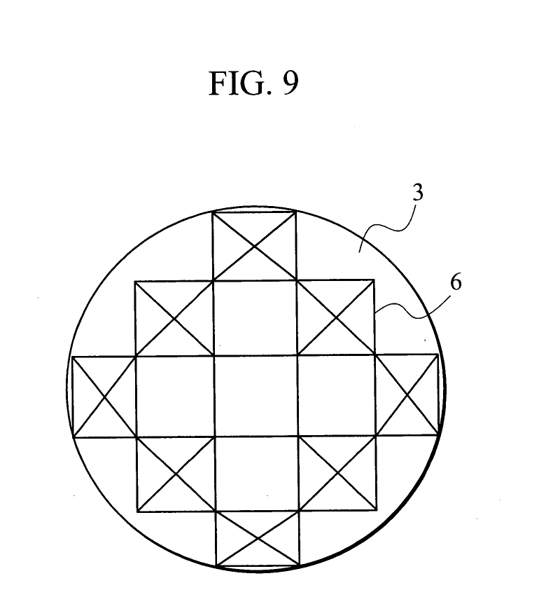

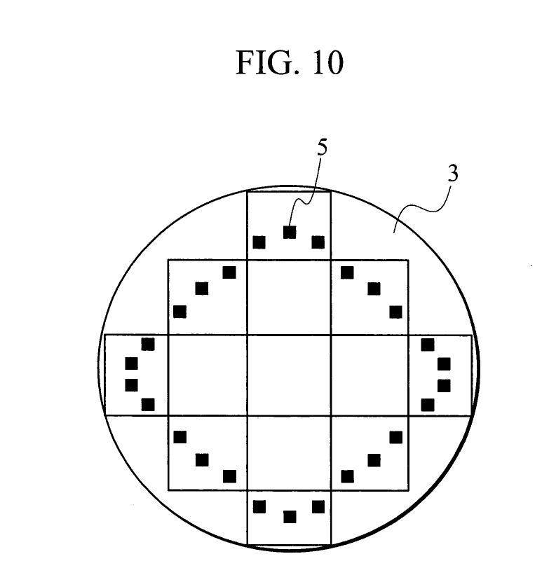

Next, in the above-described failure analysis method according to the first embodiment, along with the layout information on the plurality of circuit blocks disposed in the chip region, pass/fail maps 9a to 9i shown in FIG. 8 are subjected to a mapping display in accordance with the physical coordinates on the plane of the wafer 3. FIG. 10 shows a result of the mapping display. In FIG. 10, fault circuit blocks 5 are concentrated on a periphery of the wafer, and it is clear that the fault circuit blocks 5 form a thin arc shape (hereinafter, the faults distributed as shown in FIG. 10 are referred to as “arc periphery faults”). The arc periphery faults are the fault modes that cannot be identified by a pass/fail map by a chip region shown in FIG. 9 because of the low resolution. In FIG. 9, spots indicated by the christcross marks represent fault chip regions 6 of the wafer 3. This fault mode can be sufficiently identified by use of fail bit maps. However, due to problems such as long test time and the like, fail bit maps of the wafer are not usually obtained. On the other hand, in the above-described failure analysis method according to the first embodiment, the mapping display method using the pass/fail maps as the fault information enables recognition of such a fault mode.

For the cause of faults concentrated in the vicinity of the periphery of the wafer, various factors are conceivable. For example, a film thickness has an uneven distribution in the periphery of the wafer and where dust tends to be attached to the periphery of the wafer. Depending on the respective causes of the fault, different fault patterns occur in the fault distribution in the wafer plane, which are identified by the test after completion of the wafer process. From that perspective, classification of the fault patterns is important for fault cause clarification. The arc periphery fault identified in FIG. 10 has a geometric symmetry in its fault distribution. Thus, it is clear that the arc periphery fault is not one caused by the unevenness of the film thickness or by the attachment of dust. In order to clarify the cause of the fault, it is necessary to extract a wafer in which a similar arc-shaped fault pattern occurs and to find out a common cause therebetween. The fail bit map is obtained for limited wafers and thus has a problem that a fault mode occurring with low frequency cannot be detected due to sampling issues and the like. However, by use of the mapping display method of the pass/fail maps of the failure analysis system according to the first embodiment, data of all wafers can be displayed and thus all fault modes can be detected. For detection of the fault patterns, there is a method of viewing maps by an operator. However, it is impossible for humans to check all the produced wafers and there are problems in determination and errors in judgment.

Second Embodiment

A failure analysis system according to a second embodiment of the present invention calculates fault-extracting index by use of the mapping display result of the pass/fail maps in the failure analysis system according to the first embodiment as an input and enables automatic detection and automatic classification of fault patterns in a system LSI.

FIG. 8 shows pass/fail maps 9a to 9i obtained as a result of testing electrical characteristics of the nine circuit blocks in the chip region after completion of the wafer process of the SRAM. As shown in FIG. 8, in each of the circuit blocks, a tendency is observed in which there are more fault circuit blocks 5 in the chips in the vicinity of the wafer periphery. FIG. 9 is a pass/fail map of a chip region unit for all the circuit blocks. As shown in FIG. 9, it is also discovered that there is a tendency that more fault chip regions 6 are in the vicinity of the periphery of the wafer 3.

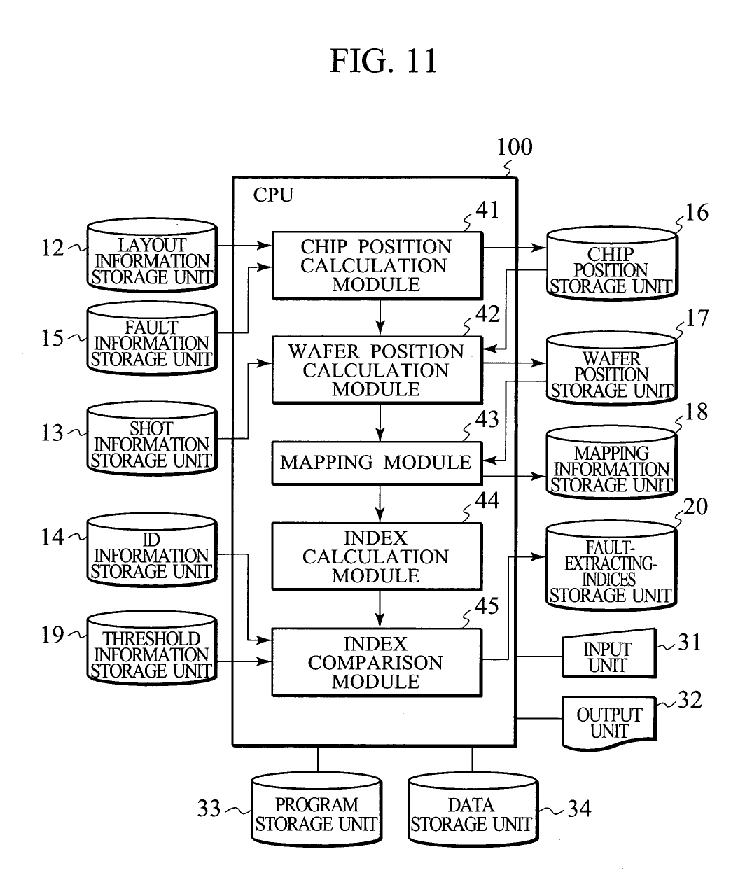

As shown in FIG. 11, the failure analysis system according to the second embodiment includes: a layout information storage unit 12; a shot information storage unit 13; an ID information storage unit 14; a fault information storage unit 15; a chip position storage unit 16; a wafer position storage unit 17; a mapping information storage unit 18; a threshold information storage unit 19; a fault-extracting-indices storage unit 20; and a central processing unit (CPU) 100. Furthermore, an input unit 31, an output unit 32, a program storage unit 33 and a data storage unit 34 are connected to the CPU 100. The CPU 100 includes a chip position calculation module 41, a wafer position calculation module 42, a mapping module 43, an index calculation module 44 and an index comparison module 45. Compared with the failure analysis system in FIG. 3 according to the first embodiment, the CPU 100 of this embodiment includes the index calculation module 44 and the index comparison module 45 besides the components included in the CPU 100 of the failure analysis system according to the first embodiment. The chip position calculation module 41, the wafer position calculation module 42 and the mapping module 43 are described in the first embodiment and thus a description thereof will be omitted herein.

The index calculation module 44 calculates the fault-extracting-indices for extracting the arc periphery fault by use of the mapping display result of the pass/fail maps. A specific calculation method of the fault-extracting-indices will be described later. Note that the index calculation module 44 can similarly calculate indices for extracting various fault modes other than the arc periphery fault. The index comparison module 45 can determine whether the arc periphery fault is present by comparing the calculated index with threshold of the index stored in the threshold information storage unit 19. The “threshold” is threshold information on fault-extracting-indices for extracting various fault modes, for example, the arc periphery fault. A result of the determination of whether the arc periphery fault is present as well as the calculated index are stored in the fault-extracting-indices information storage unit 20.

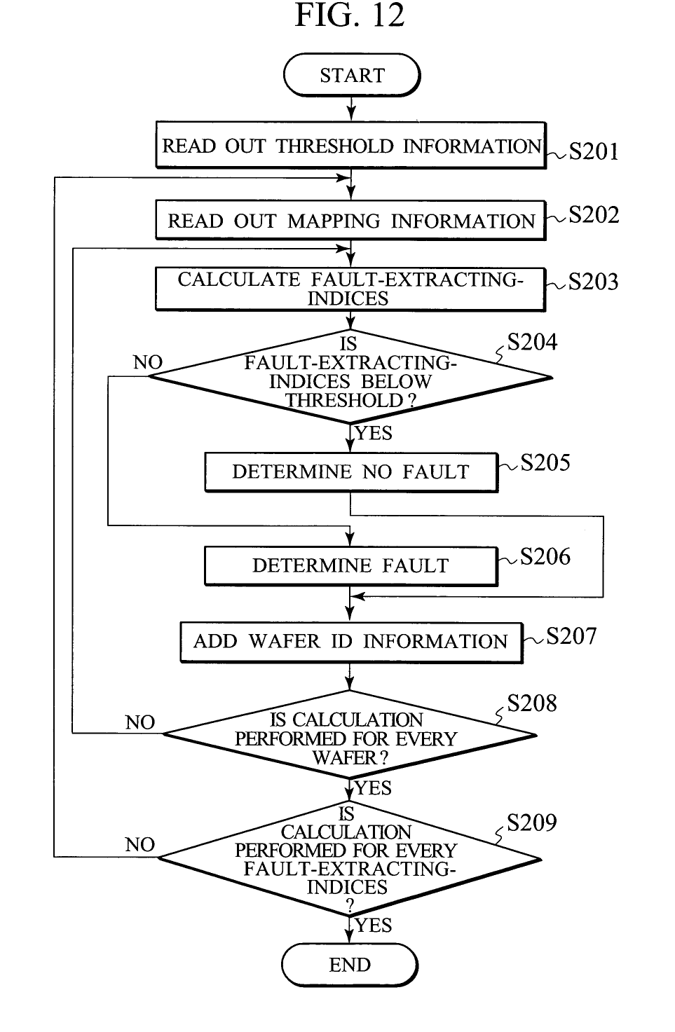

Next, a failure analysis method according to the second embodiment of the present invention will be described with reference to FIG. 12. Herein, in the above-described failure analysis method according to the first embodiment, it is based on the premise that the mapping display result has been obtained in the processing of Steps S101 to S110 by use of the pass/fail maps as the fault information.

(a) First, in Step S201, threshold is read out from the threshold information storage unit 19. Subsequently, in Step S202, the mapping display result of the pass/fail maps is read out from the mapping module 43.

(b) In Step S203, the index calculation module 44 calculates the fault-extracting-indices for extracting the arc periphery fault by use of the mapping display result of the pass/fail maps. A specific calculation method of the fault-extracting-indices will be described later.

(c) In Step S204, the index comparison module 45 determines whether the arc periphery fault is present by comparing the fault-extracting-indices calculated in Step S203 with the threshold stored in the threshold information storage unit 19. When the calculated indices are smaller than the threshold, it is determined in Step S205 that the arc periphery fault is not present. On the other hand, when the calculated indices are larger than or equal to the threshold, it is determined that the arc periphery fault is present in Step S206.

(d) In Step S207, the index comparison module 45 adds wafer ID information read out from the ID information storage unit 14 to the indices obtained in Step S203 and to the determination result of the presence of the arc periphery fault, which is determined in Steps S204 to S206. These calculated indices and determination result of the presence of the arc periphery fault, to which the wafer ID information is added, are stored in the fault-extracting-indices information storage unit 20.

(e) In Step S208, the index comparison module 45 determines whether the processing from S201 to S207 is performed for all target wafers. When the processing is not performed for all the target wafers, the processing returns to Step S203. On the other hand, when the processing has been performed for all the target wafers, the processing advances to Step S209.

(f) In Step S209, the index comparison module 45 determines whether all fault-extracting-indices are calculated. When all the fault-extracting-indices are not calculated, the processing returns to Step S202. On the other hand, when all the fault-extracting-indices are calculated, the processing is finished.

The calculation method of the fault-extracting-indices in Step S203 of FIG. 12 is described below. First, the geometric symmetry of the arc periphery fault can be represented by a perfect circle. The coordinates of the center point of the perfect circle and the radius thereof have no substantial dependence on a wafer or a wafer lot. This calculation is made possible because fault wafer position information is given as coordinates of the circuit blocks which are smaller than the chip regions on the wafer plane. Accordingly, a region where the arc periphery fault occurs is set to be region A, and a fault circuit block density dA in the region A is obtained. The density dA is obtained by dividing the number of the fault circuit blocks belonging to the region A by the number of all the circuit blocks belonging to the region A. Similarly, a region which does not belong to the region A is set to be region B and a fault circuit block density dB in the region B is obtained. Thereafter, a degree of geometrical bias pᵢ of the arc periphery fault is obtained by the equation (1).

pᵢ=−2{dB/(dA+dB)}+1 (1)

The degree of geometrical bias pᵢ takes a value “1” in the case where the faults are concentrated only in the region A, a value “0” in the case where the faults are evenly distributed over the entire wafer and a value “−1” in the case where the faults are concentrated in regions excluding the region A.

Also, as a geometrical characteristic of the arc periphery fault, the fault is designated as having a certain continuous arc length in the region A. Accordingly, when a threshold h with respect to a distance between the circuit blocks is set and the circuit blocks spaced apart by a distance within the threshold h are both fault units, the fault is regarded as a continuous fault. Thus, the distance between both of the circuit blocks is set to be “a length of a fault.” Furthermore, when the circuit blocks spaced apart by the distance within the threshold h are fault units, distances to the fault circuit blocks are sequentially added. In such a manner, the length of the fault is calculated. Accordingly, the longest length of the fault belonging to the region A is set to be a degree of continuity p_{c}.

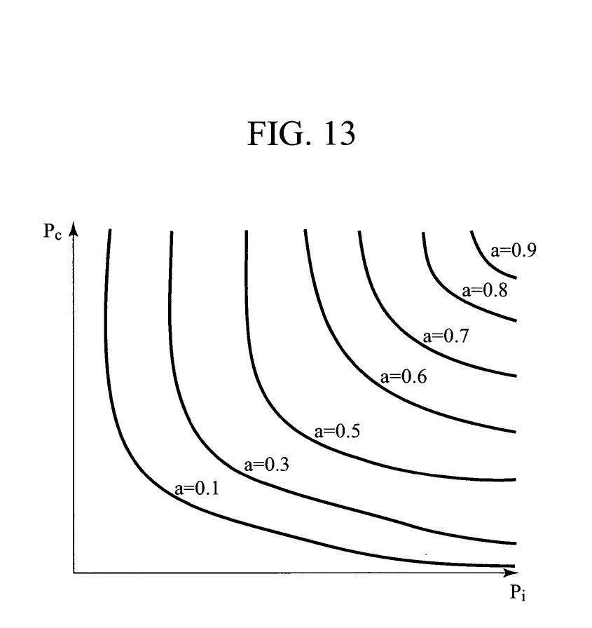

Next, as shown in FIG. 13, a two-dimensional space defined by parameters (pᵢ, p_{c}) is considered. The value of the threshold “1” is allocated to a region where the arc periphery fault is considered to be most likely to emerge, likewise a value of the threshold “0” is located to a region where the arc periphery fault is considered to be least likely to exist and a value of the threshold “0.5” is located to a region considered to be a fine line between whether the arc periphery fault will emerge. Accordingly, a contour line interpolating therebetween is obtained and thus a fault-extracting-index “a” as a scalar quantity for extracting the arc periphery fault is obtained. When this fault-extracting-index “a” has a value of the threshold 0.5 or more, it is determined that the arc periphery fault exists on the wafer. When the fault-extracting-index “a” has a value less than the threshold 0.5, it is determined that the arc periphery fault does not exist on the wafer.

As described above, by use of the information on the pass/fail maps of the respective circuit blocks in the system LSI, it is possible to calculate fault-extracting-indices that automatically detect fault modes requiring resolution equivalent to a chip region or less. Moreover, unlike the fail bit maps, data obtained in all wafers can be used and thus even fault modes occurring less frequently can be detected.

As described above, according to the second embodiment of the present invention, faults in the system LSI can be automatically detected with high precision without adversely affecting productivity of a factory.

Third Embodiment

A failure analysis system according to a third embodiment of the present invention also enables an automatic classification of unknown fault patterns that are not previously registered.

By use of the failure analysis methods according to the first and second embodiments, it was described that construction of a failure analysis system with a high spatial resolution is possible by use of the test results of all the plurality of small capacitance circuit blocks scattered in the chip region, which are the characteristics of the chip layout of the system LSI, without using the fail bit maps which are limited in the number of wafers that can be examined for obtaining data. According to the methods, it has become apparent that various fault patterns including fault modes occurring less frequently exist in production of the system LSI. However, by use of the failure analysis methods according to the first and second embodiments, automatic fault detection by use of large quantities of data is made possible. Thus, the number of unknown fault patterns itself becomes enormous. Consequently, the failure analysis system according to the third embodiment of the present invention enables an automatic classification as to which category each of the unknown fault patterns belongs.

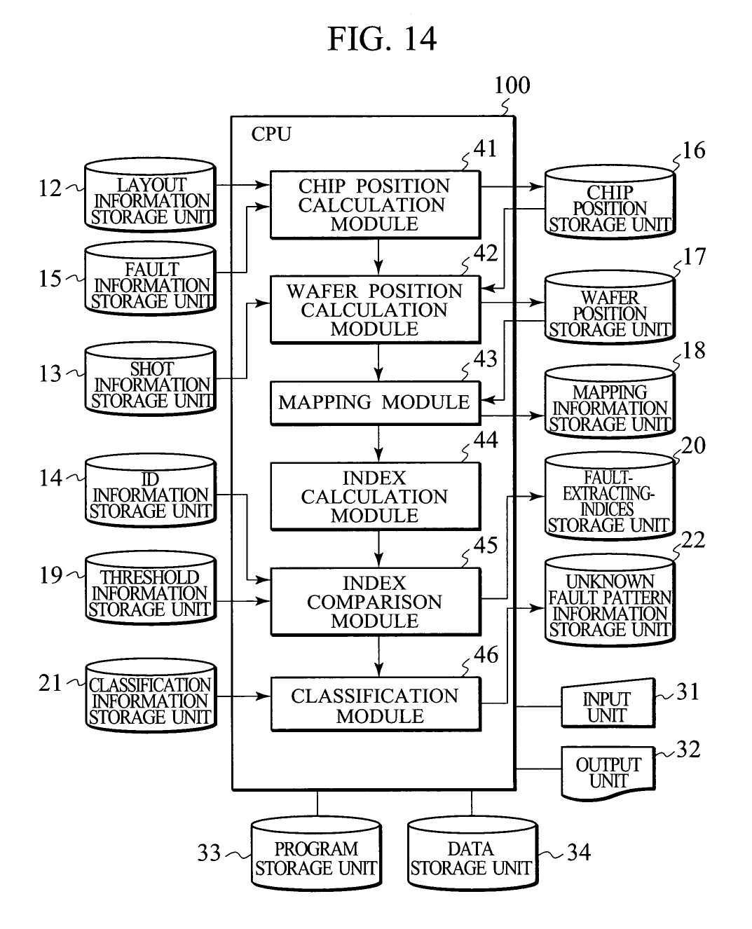

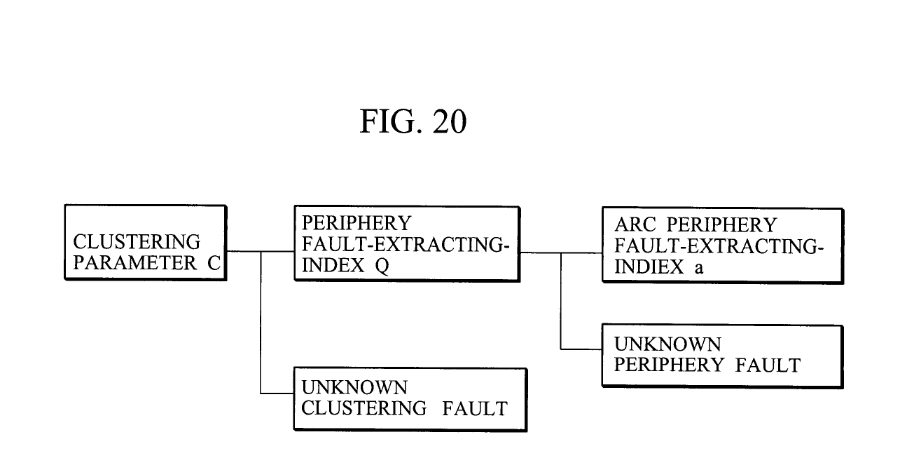

As shown in FIG. 14, the failure analysis system according to the third embodiment includes: a layout information storage unit 12; a shot information storage unit 13; an ID information storage unit 14; a fault information storage unit 15; a chip position storage unit 16; a wafer position storage unit 17; a mapping information storage unit 18; a threshold information storage unit 19; a fault-extracting-indices information storage unit 20; a classification information storage unit 21; an unknown fault pattern information storage unit 22; and a central processing unit (CPU) 100. Furthermore, an input unit 31, an output unit 32, a program storage unit 33 and a data storage unit 34 are connected to the CPU 100. The CPU 100 includes a chip position calculation module 41, a wafer position calculation module 42, a mapping module 43, an index calculation module 44, an index comparison module 45 and a classification module 46. Compared with the failure analysis system of FIG. 11 according to the second embodiment, the CPU 100 of this embodiment includes the classification module 46 besides the components included in the CPU 100 of the failure analysis system according to the second embodiment. The classification information storage unit 21 stores classification information, as shown in FIG. 20, in which fault-extracting-indices are classified. The chip position calculation module 41, the wafer position calculation module 42, the mapping module 43, the index calculation module 44 and the index comparison module 45 are described in the second embodiment and thus a description thereof will be omitted herein.

The classification module 46 sets a hierarchical structure between calculated fault-extracting-indices and performs detection and classification of unknown fault modes. The detected and classified fault modes are stored in the unknown fault pattern information storage unit 22. Note that a user can recognize the classified unknown fault modes by referring to the unknown fault pattern information storage unit 22 and can add a new fault-extracting-index algorithm to the program storage unit 33. Moreover, the user can also register a new calculation method of a fault-extracting-index in the program storage unit 33.

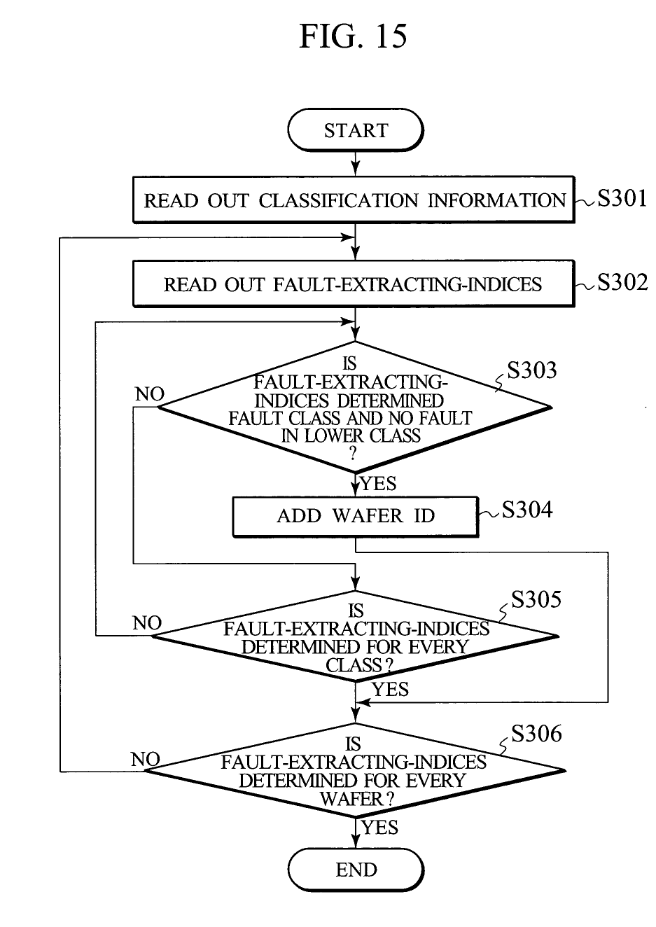

Next, a failure analysis method according to the third embodiment of the present invention is described with reference to FIG. 15. Herein, the fault-extracting-indices calculation result and the determination result of the presence of the fault modes have been obtained in the processing of Steps S201 to S209 by use of the pass/fail maps as the fault information in the above-described failure analysis method according to the second embodiment.

(a) First, in Step S301, classification information as shown in FIG. 20, in which fault-extracting-indices are classified, is read out from the classification information storage unit 21. Subsequently, in Step S302, the fault-extracting-indices calculation result and the determination result of the presence of the fault modes, to which the wafer ID information is added, are read out from the index comparison module 45.

(b) In Step S303, the classification module 46 sets a hierarchical structure between calculated fault-extracting-indices and performs detection and classification of unknown fault modes based on the classification information in which the fault-extracting-indices are classified, read out in Step S301. In the detection of the unknown fault modes, it is determined whether there is a fault in upper-level fault-extracting-index and if there is no fault in lower-level fault-extracting-index. A specific processing method of the classification module 46 will be described later. When, in Step S304, there is a fault in the upper-level fault-extracting-index and there is no fault in the lower-level fault-extracting-index, the classification module 46 recognizes the unknown fault pattern as one belonging to the upper-level fault-extracting-index and adds the wafer ID information read out from the ID information storage unit 14 to the unknown fault pattern belonging to the upper-level fault-extracting-index. This unknown fault pattern added the wafer ID information is stored in the unknown fault pattern information storage unit 22. On the other hand, in any cases except a case where there is a fault in the upper-level fault-extracting-index and there is no fault in the lower-level fault-extracting-index, the processing advances to Step S305.

(c) In Step S305, the classification module 46 determines whether the processing of S301 to S303 is performed for all classes of fault-extracting-indices. When the processing is not performed for all the classes of fault-extracting-indices, the processing returns to Step S303. On the other hand, when the processing is performed for all the classes of fault-extracting-indices, the processing advances to Step S306.

(d) In Step S306, the classification module 46 determines whether the processing of S301 to S305 is performed for all target wafers. When the processing is not performed for all the target wafers, the processing returns to Step S302. On the other hand, when the processing is performed for all the target wafers, the processing is finished.

The processing method of the classification module 46 in Step S303 of FIG. 15 will be described in detail below.

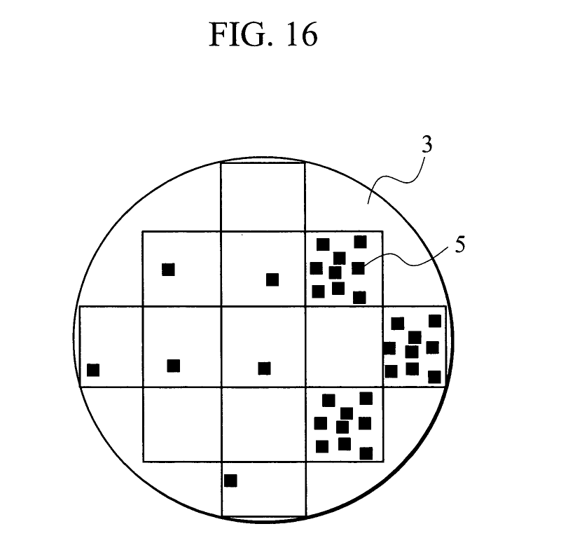

In the second embodiment described above, the fault-extracting-indices of the arc periphery fault as a fault mode have been defined. Thereafter, a fault mode having a pattern in a wafer shown in FIG. 16 is assumed to occur. In the fault mode shown in FIG. 16, faults are biased toward the periphery of the wafer 3. However, all circuit blocks in a chip region are fault circuit blocks 5 and thus the fault mode is clearly different from the arc periphery fault shown in FIG. 10. Therefore, it is also considered that a cause for the occurrence of the fault mode is different and thus a classification different from the arc periphery fault of FIG. 10 is required. The fault-extracting-index “a” of the arc periphery fault of the wafer 3 shown in FIG. 16 is 0.23, which is below the threshold 0.5. Therefore, in the failure analysis system according to the second embodiment, it is recognized that an arc periphery fault does not exist on the wafer.

In the failure analysis system according to the third embodiment, a clustering parameter C of the wafer 3 shown in FIG. 16 is calculated by incorporating a clustering parameter computational algorithm into the failure analysis system according to the second embodiment. Here the clustering parameter C is defined as a weight of a negative binomial distribution. As a result, the clustering parameter of C=32% is obtained, which indicates some kind of cluster occurrence. From the above-described result, the fault pattern of FIG. 16 can be automatically determined to be the fault pattern in which some kind of unknown cluster fault occurs.

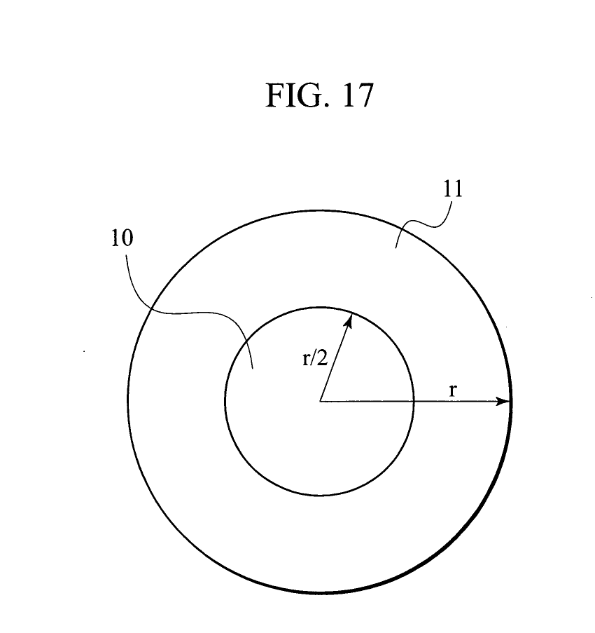

Each of the fault modes shown in FIGS. 10 and 16 is a type of periphery fault. Herein, a fault-extracting-index extracting the entire periphery fault is considered. As shown in FIG. 17, a radius of the wafer is set to r and two regions are considered, which include: an internal circumference region 10 of the wafer from the wafer center to r/2; and a periphery region 11 from r/2 to the wafer edge. The number of all circuit blocks belonging to the internal circumference region 10 is n₀ and the number of all circuit blocks belonging to the periphery region 11 is n₁. Additionally, the number of fault circuit blocks belonging to the internal circumference region 10 is f₀ and the number of fault circuit blocks belonging to the periphery region 11 is f₁. Fault circuit block densities d₀ and d₁ of the respective internal circumference and the periphery regions 10 and 11 are defined by the equations (2) and (3), respectively.

d₀=f₀/n₀ (2)

d₁=f₁/n₁ (3)

Degrees of bias k of the faults between the internal circumference and the periphery of the wafer are defined by the equation (4).

k=−2{d₀/(d₀+d₁)}+1 (4)

In the equation (4), k takes continuous values from +1 to −1. For example, if the faults are completely biased toward the periphery region 11, k is +1. If the faults are completely biased toward the internal circumference region 10, k is −1. If the faults are evenly distributed over the wafer, k is 0.

Moreover, the biases between the internal circumference and the periphery regions 10 and 11 are determined by the χ-square test. Specifically, expected values e₀ and e₁ of the numbers of the fault circuit blocks in the respective internal circumference and periphery regions 10 and 11 are obtained by the equations (5) and (6), respectively.

e₀=(f₀+f₁)·{n₀/(n₀+n₁)} (5)

e₁=(f₀+f₁)·{n₁/(n₀+n₁)} (6)

Thereafter, a χ-square test value is calculated by the equation (7).

χ²=(f₀−e₀)²/e₀+(f₁−e₁)²/e₁ (7)

A value obtained by substituting the value of the equation (7) in a one-degree-of-freedom χ-square distribution function is P. It is determined by use of P whether a significant difference exists between the biases of the fault distributions of the internal circumference and the periphery regions 10 and 11.

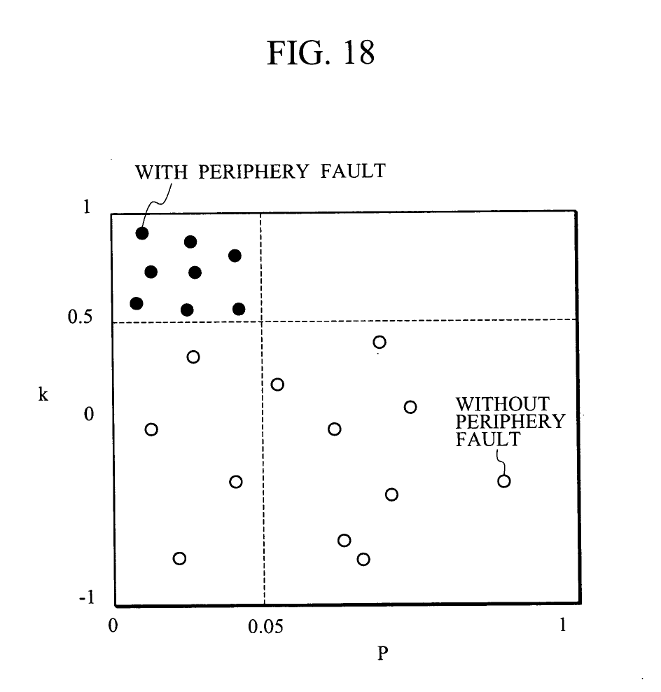

Here, a two-dimensional parameter space defined by k of the equation (4) and P calculated from the χ² value of the equation (7) is considered. FIG. 18 shows a result of plotting the presence of periphery faults, which are determined by an operator for twenty wafers, in the parameter space. The operator determines the wafer to be a wafer with periphery faults if the faults tend to be biased toward the periphery of the wafer 3, besides the fault modes shown in FIGS. 10 and 16. From the two-dimensional parameter space, it is determined that there are regions where periphery fault wafers exist in the range obtained by the following inequalities.

k≧0.5 (8)

P≦0.05 (9)

Specifically, it is determined that, by use of the space shown in FIG. 18, which is defined by the two parameters k and P, all the periphery faults can be extracted.

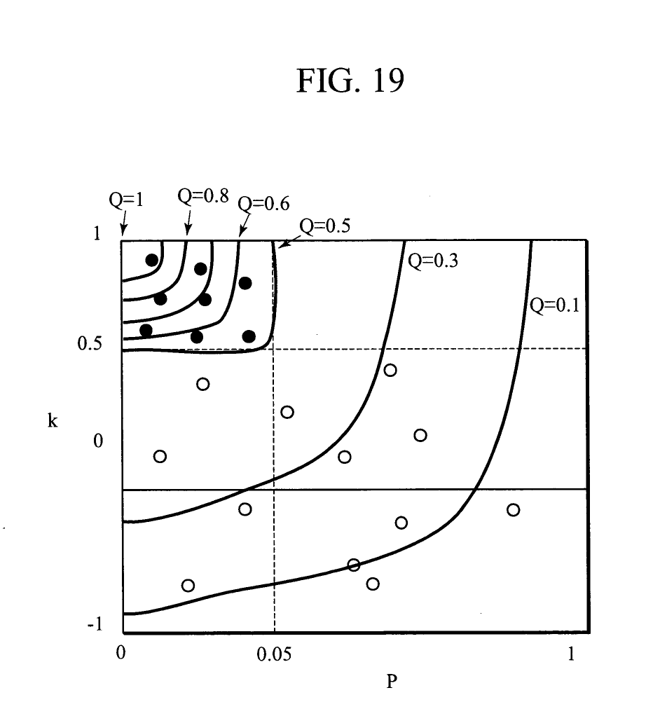

Next, the periphery faults expressed by the two parameters k and P are expressed by one scalar quantity of a fault-extracting-index Q as shown in FIG. 19. In FIG. 19, Q=1 is obtained at the point (k, P)=(1, 0), Q=0.5 is obtained on a boundary line of a periphery fault region surrounded by the line of k=0.5 and the line of P=0.05 and Q=0 is obtained on the line of k=−1 and the line of P=1, and then contour lines interpolating therebetween are obtained. The fault-extracting-index Q is set to be a scalarized index for extracting all the periphery faults.

Herein, the hierarchical structure shown in FIG. 20 is considered for the clustering parameter C for extracting all cluster faults, the fault-extracting-index Q for extracting all the periphery faults and the fault-extracting-index “a” for extracting the arc periphery fault. When a fault exists that can be detected by the clustering parameter C for extracting all the cluster faults but cannot be detected by the fault-extracting-index Q for extracting all the periphery faults, the fault can be determined to be an unknown cluster fault other than the periphery fault. Similarly, when a fault exists that can be detected by the fault-extracting-index Q for extracting all the periphery faults but cannot be detected by the fault-extracting-index “a” for extracting the arc periphery fault, the fault can be determined to be an unknown periphery fault other than the arc periphery fault.

In the above-described manner, by constructing the hierarchical structure with the upper-level fault-extracting-index for extracting wide-ranging fault modes and the lower-level fault-extracting-index for extracting only a specific fault mode, not only the detection of the presence of unknown fault modes but also the classification thereof can be performed. A system having this hierarchical structure of fault-extracting-indices classifies an unknown fault mode in given classes and warns the operator of emergence of the unknown fault mode. The operator views a result of a mapping display for fail bit maps of the fault mode or pass/fail maps thereof and recognizes the fault mode. Then, the operator adds a fault-extracting-index for extracting the fault mode to the failure analysis system. By repeating this operation, it is possible to increase the number of fault modes that can be automatically extracted and classified by the failure analysis system. Note that the algorithm described in the third embodiment of the present invention can be constructed as a system using abundant fault information in the system LSI by use of the failure analysis method according to the second embodiment.

As described above, according to the third embodiment, the hierarchical structure between the fault-extracting-indices enables the unknown fault modes to be detected and automatically classified in the hierarchical structure.

(Manufacturing Method for Semiconductor Device)

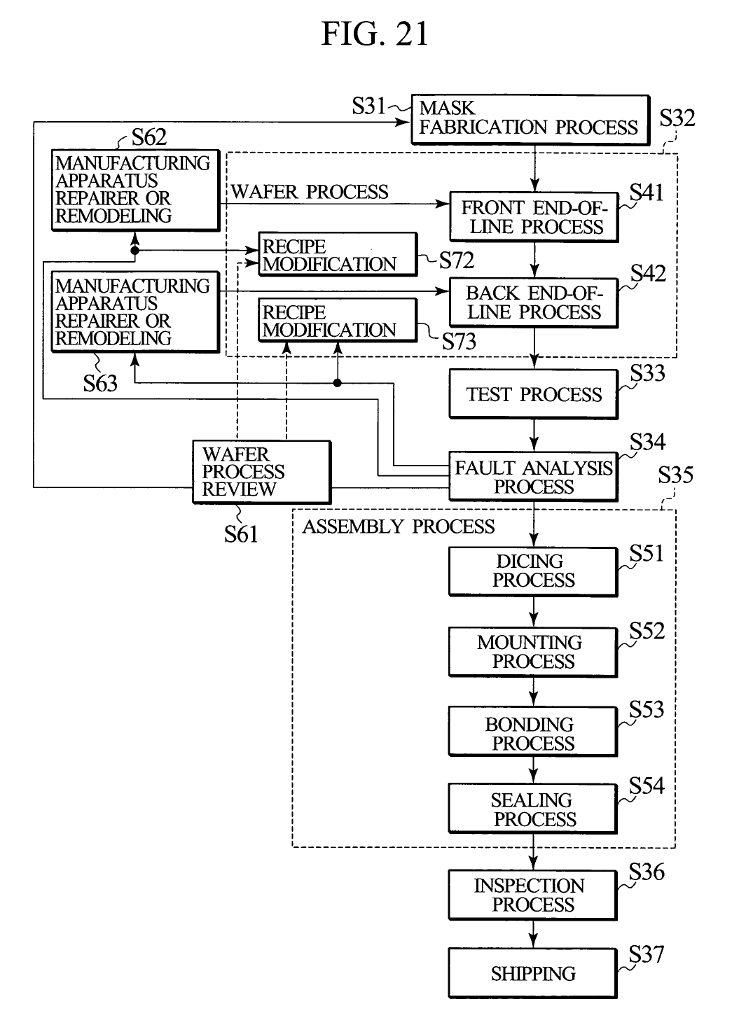

Next, with reference to FIG. 21, a description will be given of a manufacturing method for a semiconductor device by use of the above-described failure analysis method. The manufacturing method for a semiconductor device according to the embodiment of the present invention includes: a pattern design process (not shown); a mask fabrication process of Step S31; a wafer process of Step S32; a test process of Step S33; a fault analysis process of Step S34; an assembly process of Step S35; and an inspection process of Step S36. Thereafter, the processing moves on to a shipping process of Step S37.

Usually, up to the mask fabrication process of Step S31 is a preparation stage, and a series of processes from Step S32 to Step S35 are repeatedly performed with lot-by-lot processing. Steps S36 and S37 may be either linked to the lot or conducted as a process independent of the lot. After a certain number of products are accumulated, the processing moves to the shipping process of Step S37. A detailed description of the respective processes will be given below.

(a) First, based on the results of a process simulation, a device simulation, a circuit simulation and the like, necessary pieces of mask data for providing a surface pattern of a system LSI including circuit blocks are prepared by use of a CAD system. Thereafter, based on the mask data necessary for achieving respective layers and inner structures on a wafer corresponding to stages of the respective processes of the semiconductor manufacturing steps, a set of necessary pieces of masks (reticles) is fabricated in Step S31 by use of a pattern generator such as an electron beam exposure apparatus.

(b) Next, in Step S41, a front end-of-line process for the semiconductor wafer is performed by repeating a photolithography process using the respective reticles required for the respective processes. For example, by use of the corresponding reticle, photoresist applied on the semiconductor wafer is exposed by a stepper, and a selective diffusion process, a selective ion implantation process and the like are performed by use of the patterned mask. Furthermore, various kinds of thin films formed by an oxidation process or a CVD process are etched by use of a photoresist mask or the like, which is formed by using another corresponding reticle. Moreover, on the surface of the semiconductor wafer, trenches and the like are selectively formed.

(c) Thereafter, in Step S42, by delineating a desired pattern by use of the reticle required for each process, wiring processing is carried out for the semiconductor surface (a back end-of-line process). In the back end-of-line process in Step S42, a deposition process of an insulating film by CVD and the like, an opening process of contact holes (via holes) for the insulating film and a deposition process of a metal film by vacuum evaporation, sputtering or the like are sequentially repeated. Thus, a multilayer interconnection structure is formed.

(d) Next, in the test process of Step S33, probes are put on pads of chip region patterns on the wafer, and electrical characteristics are measured. From the measurement result of the electrical characteristics, the respective chip region patterns are separated into a nondefective chip region and a defective chip region. A fail bit map, a pass/fail map and the like, which are obtained as a result of this test, are stored in the fault information storage unit 15 shown in FIG. 3.

(e) In Step S34, fault information on such as the fail bit map, the pass/fail map and the like is read from the fault information storage unit 15. According to the flowchart in FIG. 4., fault wafer positions in the wafer are calculated from this fault information, and a mapping display is performed in accordance with physical coordinates on the wafer plane. In the mapping display method, as described above, the chip position calculation module 41 calculates fault chip positions in the chip region based on the layout information and the fault information. Subsequently, the wafer position calculation module 42 calculates fault wafer positions in the wafer based on shot position information and calculated fault information in the chip region. Thereafter, the mapping module 43 performs the mapping display of the fault wafer positions in the wafer in accordance with the physical coordinates on the wafer plane.

Furthermore, in accordance with the flowchart shown in FIG. 12, fault patterns are automatically detected and classified. In the automatic detection and automatic classification method, as described above, the index calculation module 44 calculates fault-extracting-indices for extracting, for example, an arc periphery fault by use of the mapping display result. Subsequently, the index comparison module 45 compares the calculated fault-extracting-indices with the threshold stored in the threshold information storage unit 19 and determines whether the arc periphery fault is present. When the calculated fault-extracting-indices are smaller than the threshold, it is determined that no arc periphery fault is present. When the calculated fault-extracting-indices are larger than or equivalent to the threshold, it is determined that an arc periphery fault is present.

Furthermore, in accordance with the flowchart shown in FIG. 15, unknown fault patterns, which are not previously registered in the failure analysis system, are also automatically classified. In the automatic classification method, as described above, the classification module 46 sets the hierarchical structure between the calculated fault-extracting-indices and performs the detection and classification for the unknown fault modes. Herein, the classification module 46 determines whether there is a fault in the upper-level fault-extracting-index and there is no fault in the lower-level fault-extracting-index based on the classification information in which the fault-extracting-indices are classified, in the classification information storage unit 21 and determines the unknown fault mode to be the unknown fault pattern belonging to the upper-level fault-extracting-index when there is a fault in the upper-level fault-extracting-index and no fault in the lower-level fault-extracting-index. If a manufacturing process causing the fault pattern can be determined from the specified fault pattern, the manufacturing process for the wafer process is reviewed in Step S61 and repair or remodeling of a manufacturing apparatus related to the manufacturing process causing the fault is performed in Steps S62 and S63. Alternatively, in Steps S72 and S73, a specific condition (recipe) of the manufacturing process, which has caused the fault, is modified. Thereafter, when the fault manufacturing process can resolve the problem by redoing the deposition of the thin film and the like, the fault thin film is entirely removed and the processing is started over from the process which caused the failure. Further, when the manufacturing process cannot be redone, the fault analysis result is fed back so as to use a repaired or remodeled manufacturing apparatus or to use a modified recipe for processes starting from the next lot. Thus, it is possible to improve the yield of the next lot. Moreover, when there is a problem in the design itself of the wafer process of Step S32, the processing is started over from the mask fabrication process of Step S31 (if necessary, a process simulation and the like are also added).

(f) When the wafer process is completed, the wafer is divided into chips with a predetermined chip size by use of a dicing apparatus such as a diamond blade in a dicing process of Step S51. Thereafter, the chip is mounted on a packaging material in a mounting process of Step S52, and an electrode pad on the chip and a lead of a lead frame are connected to each other by a gold wire or a bump in a bonding process of Step S53. Next, in a sealing process of Step S54, a required package assembly process such as sealing of resin and the like is carried out.

(g) Next, through a characteristic inspection of performance and functions of a semiconductor device and predetermined inspections such as states of lead shape and dimension, a reliability test and the like in an inspection process of Step S36, a semiconductor device is completed. In Step S37, the semiconductor device that has cleared all the above-described processes is packaged for protection from moisture, static electricity and the like and is shipped as a product.

Other Embodiments

In the embodiments of the present invention, a description has been given based on the premise that, for example, the chip position calculation module 41, the wafer position calculation module 42, the mapping module 43, the index calculation module 44, the index comparison module 45 and the classification module 46 are included in one central processing unit (CPU). However, the above components may be separately included in two or more central processing units. In that case, it is assumed that a bus and the like connects the central processing units so as to enable exchange of data therebetween.

Various modifications will become possible for those skilled in the art after receiving the teachings of the present disclosure without departing from the scope thereof.

What is claimed is:

1. A failure analysis system, comprising:
a chip position calculation module configured to calculate fault chip positions of a plurality of circuit blocks in a chip region based on layout information on the circuit blocks positioned in the chip region and fault information on the circuit blocks;
a wafer position calculation module configured to calculate fault wafer positions in a wafer based on the fault chip positions and position information showing a chip region layout in a wafer plane; and
a mapping module configured to perform a mapping display of the fault wafer positions in accordance with physical coordinates on the wafer plane.

2. The system of claim 1, wherein the fault information is one of fail bit maps and pass/fail maps of the circuit blocks.

3. The system of claim 1, further comprising:
an index calculation module configured to calculate fault-extracting-index for extracting a fault mode based on a result of the mapping display; and
an index comparison module configured to compare a threshold of the fault-extracting-index for extracting a specific fault mode to the calculated fault-extracting-index and determines the presence of the specific fault mode.

4. The system of claim 3, wherein the fault mode is an arc periphery fault.

5. The system of claim 4, wherein the arc periphery fault is biased toward a periphery region of the wafer and has a geometric symmetry.

6. The system of claim 3, further comprising a classification module configured to set a hierarchical structure between a plurality of fault-extracting-indices and performs detection and classification of unknown fault modes based on classification information in which the fault-extracting-indices are classified in the hierarchical structure.

7. The system of claim 6, wherein the hierarchical structure includes at least an arc periphery fault, a periphery fault including the arc periphery fault and a cluster fault including the periphery fault.

8. A failure analysis method, comprising:
reading out layout information on a plurality of circuit blocks disposed in a chip region, position information showing a chip region layout in a wafer plane and fault information on the circuit blocks;
calculating fault chip positions in the chip region of the circuit blocks based on the layout information and the fault information;
calculating fault wafer positions in a wafer based on the position information and the fault chip positions; and
subjecting the fault wafer positions to a mapping display in accordance with physical coordinates on the wafer plane.

9. The method of claim 8, wherein the fault information is one of fail bit maps and pass/fail maps of the circuit blocks.

10. The method of claim 8, further comprising:
calculating fault-extracting-index for extracting a fault mode based on a result of the mapping display; and
determining the presence of the fault mode by comparing the fault-extracting-index with a threshold stored in a threshold information storage unit.

11. The method of claim 10 wherein the fault mode is an arc periphery fault.

12. The method of claim 11, wherein the fault-extracting-index is calculated by a degree of bias of fault densities in a region where the arc periphery fault occurs and by a degree of continuity of the longest continuous faults adjacent two of which is spaced apart by a distance within a threshold in the region where the arc periphery fault occurs.

13. The method of claim 10, further comprising:
setting a hierarchical structure between a plurality of fault-extracting-indices; and
performing detection and classification of unknown fault modes based on classification information in which the fault-extracting-indices are classified in the hierarchical structure, and a result of determining the presence of the fault mode for each of the fault-extracting-indices.

14. The method of claim 13, wherein the hierarchical structure includes at least an arc periphery fault, a periphery fault including the arc periphery fault and a cluster fault including the periphery fault.

15. The method of claim 13, wherein the fault mode is classified as the unknown fault mode concerning upper-level fault-extracting-index when it is determined that there is a fault in the upper-level fault-extracting-index of the hierarchical structure and there is no fault in fault-extracting-index one level lower than the upper-level fault-extracting-index.

16. A computer program product configured to be executed by a computer, comprising:
an instruction of reading out layout information on a plurality of circuit blocks disposed in a chip region, position information showing a chip region layout in a wafer plane and fault information on the circuit blocks;
an instruction of calculating fault chip positions in a chip region of the circuit blocks based on the layout information and the fault information;
an instruction of calculating fault wafer positions in a wafer based on the position information and the fault chip positions; and
an instruction of subjecting the fault wafer positions to a mapping display in accordance with physical coordinates on the wafer plane.

17. A manufacturing method for a semiconductor device, comprising:
fabricating a plurality of integrated circuits on a wafer, by assigning a plurality of chip regions for each of the integrated circuits such that each of the chip regions has a plurality of circuit blocks disposed therein, by sequentially executing a plurality of manufacturing processes;
obtaining fault information by measuring characteristics of the circuit blocks, respectively;
detecting a fault based on a result of a mapping display performed for the fault information in accordance with physical coordinates on a wafer plane by use of layout information on the circuit blocks disposed in the chip region; and
performing at least one of a repair of a manufacturing apparatus used for the manufacturing, a remodeling of the manufacturing apparatus, and a modification of a recipe of a specific manufacturing process in the plurality of manufacturing processes causing the fault to occur.

18. The method of claim 17, wherein the fault information is one of fail bit maps and pass/fail maps of the circuit blocks.

19. The method of claim 17, wherein the detection of the fault comprises:
calculating fault-extracting-index of a fault mode based on the result of the mapping display; and
determining the presence of the fault mode by comparing the fault-extracting-index with a threshold stored in a threshold information storage unit.

20. The method of claim 19, wherein the fault mode is an arc periphery fault.

21. The method of claim 20, wherein the fault-extracting-index is calculated by a degree of bias of fault densities in a region where the arc periphery fault occurs and by a degree of continuity of the longest continuous faults adjacent two which is spaced apart by a distance within a threshold in the region where the arc periphery fault occurs.

22. The method of claim 19, wherein the detection of the fault further comprises:
setting a hierarchical structure between a plurality of fault-extracting-indices; and
performing detection and classification of unknown fault modes based on classification information in which the fault-extracting-indices are classified in the hierarchical structure, and a result of determining the presence of the fault mode for each of the fault-extracting-indices.

23. The method of claim 22, wherein the hierarchical structure includes at least an arc periphery fault, a periphery fault including the arc periphery fault and a cluster fault including the periphery fault.

24. The method of claim 22, wherein the fault mode is classified as the unknown fault mode concerning upper-level fault-extracting-index when it is determined that there is a fault in the upper-level fault-extracting-index of the hierarchical structure and there is no fault in fault-extracting-index one level lower than the upper-level fault-extracting-index.
